(19) United States
(12) Patent Application Publication
(10) Pub. No.: US 2013/0271328 A1
(43) Pub. Date: Oct. 17, 2013

(54) Impedance Reference Structures for Radio-Frequency Test Systems

(71) Applicants: Joshua G. Nickel, San Jose, CA (US); Jr-Yi Shen, Sunnyvale, CA (US); William J. Noellert, Sunnyvale, CA (US)

(72) Inventors: Joshua G. Nickel, San Jose, CA (US); Jr-Yi Shen, Sunnyvale, CA (US); William J. Noellert, Sunnyvale, CA (US)

(21) Appl. No.: 13/448,180

(22) Filed: Apr. 16, 2012

(51) Int. Cl. G01R 29/08

(52) U.S. Cl. 343/703

(57) ABSTRACT

A radio-frequency test system configured for testing device structures under test is provided. The test system may include a radio-frequency tester, a test probe that is coupled to the tester, and an auxiliary test fixture that receives the device structures under test. During testing, the device structures under test may be mounted on the auxiliary test fixture. The auxiliary test fixture may provide a ground contact point and a ground reference plane. The device structures under test may include a radio-frequency circuit coupled to a conductive member via a signal path. During testing, the test probe may mate with the conductive member on the device structures under test and the ground contact point on the auxiliary test fixture. The ground reference plane in the auxiliary test fixture may serve to provide proper grounding for the signal path to help improve the accuracy of test results associated with the radio-frequency circuit.

### BACKGROUND

This relates generally to testing, and more particularly, to testing electronic device structures.

Electronic devices such as computers, cellular telephones, music players, and other electronic equipment are often provided with wireless communications circuitry. In a typical configuration, the wireless communications circuitry includes an antenna that is coupled to a transceiver on a printed circuit board via a transmission line path. Circuitry such as filters, radio-frequency amplifiers, radio-frequency switches, and other conductive structures may be interposed in the transmission line path connecting the transceiver to the antenna. The antenna performance of an electronic device may depend on how accurately these radio-frequency circuits are manufactured. Manufacturing defects present in radio-frequency circuits (i.e., defects due to process variation and non-ideal fabrication environments) may have a negative impact on the device performance. For example, if defective parts are assembled in a finished device, the finished device may exhibit unsatisfactory wireless performance during production testing. Detection of faults only after assembly is complete results in costly device scrapping or extensive reworking.

It would therefore be desirable to be able to provide improved ways in which to detect faults during the manufacturing of antenna device structures.

### SUMMARY

A wireless electronic device may include antenna device structures that form part of an antenna or other device structures. Prior to being assembled within a device, an antenna structure may be tested to ensure that circuits on the antenna structure satisfy performance criteria. The circuits (e.g., low noise amplifiers, matching circuits, filters, etc.) on the antenna structure may be interconnected via signal traces (as an example).

A test system may be provided that includes a radio-frequency tester, at least one test probe with pins or other contacts, and an auxiliary test structure configured to receive the antenna device structure under test. The radio-frequency tester may generate radio-frequency test signals in a range of frequencies. The antenna device structure under test may be attached to the auxiliary test structure during testing. The auxiliary test structure may serve to provide a ground contact probe point for the test probe and may also serve to provide a ground reference place for the signal traces on the antenna device structure.

The test probe may have a signal pin that mates with a corresponding signal contact probe point on the antenna device structure and may have a ground pin that mates with the ground contact probe point on the auxiliary test structure. Coupled in this arrangement, the test signals generated from the tester may be applied to the components and associated structures on the antenna device structures. The one test probe (and optionally additional test probes) may be used to receive corresponding signals reflected and emitted from the antenna structure under test.

Reflection coefficient and forward transfer coefficient data may be computed from the transmitted and received radio-frequency signals. The forward transfer coefficient data or other test data may be compared to reference data to determine whether the antenna structure under test satisfies design criteria.

Further features of the present invention, its nature and various advantages will be more apparent from the accompanying drawings and the following detailed description.

### BRIEF DESCRIPTION OF THE DRAWINGS

FIG. 1 is a schematic diagram of an illustrative electronic device with wireless communications circuitry in accordance with an embodiment of the present invention.

FIG. 2 is a diagram of a conventional test system for testing a conductive pin.

FIG. 3 is a diagram of an illustrative test system that includes an auxiliary test structure to which antenna structures under test may be attached in accordance with an embodiment of the present invention.

FIGS. 4A and 4B are top views showing how an antenna structure under test may be mounted on the auxiliary test structure of the type shown in FIG. 3 in accordance with an embodiment of the present invention.

FIG. 4C is a cross-sectional side view of an antenna structure under test being mounted on the auxiliary reference structure of the type shown in FIG. 3 in accordance with an embodiment of the present invention.

FIG. 5 is a diagram of an illustrative antenna having multiple feeds in accordance with an embodiment of the present invention.

FIG. 6 is a diagram of an illustrative inverted-F antenna with multiple feeds in accordance with an embodiment of the present invention.

FIG. 7 is a diagram of an illustrative loop antenna with multiple feeds in accordance with an embodiment of the present invention.

FIG. 8 is a diagram of an illustrative electronic device of the type shown in FIG. 1 showing how structures in the device may form a ground plane and antenna resonating element structures in accordance with an embodiment of the present invention.

FIG. 9 is a diagram showing how device structures of the type shown in FIG. 8 may be used in forming an antenna with multiple feeds in accordance with an embodiment of the present invention.

FIG. 10 is a diagram of an antenna of the type shown in FIG. 9 with multiple feeds and associated wireless circuitry such as filters and matching circuits in accordance with an embodiment of the present invention.

FIG. 11 is a diagram showing how frequency responses of filter circuitry associated with the first and second antenna feeds of FIG. 10 may be configured in accordance with an embodiment of the present invention.

FIG. 12 is a diagram showing an illustrative antenna feed structure configured to mate with corresponding circuitry on a printed circuit board in accordance with an embodiment of the present invention.

FIGS. 13A and 13B are top views showing how the antenna feed structure of FIG. 12 may be mounted on an auxiliary test structure of the type shown in FIG. 3 in accordance with an embodiment of the present invention.

FIG. 14 is a graph in which forward transfer coefficient magnitude data that has been gathered using a test system of the type shown in FIG. 3 has been plotted as a function of applied signal frequency in accordance with an embodiment of the present invention.

FIG. 15 is a graph in which forward transfer coefficient phase data that has been gathered using a test system of the type shown in FIG. 3 has been plotted as a function of applied signal frequency in accordance with an embodiment of the present invention.

FIG. 16 is a diagram showing an illustrative auxiliary test structure configured to receive an antenna structure that contains a radio-frequency circuit in accordance with an embodiment of the present invention.

FIG. 17 is a diagram of an illustrative antenna tuning element based on a variable capacitor in accordance with an embodiment of the present invention.

FIGS. 18 and 19 are diagrams of an illustrative antenna tuning element based on a switch in accordance with an embodiment of the present invention.

FIG. 20 is a diagram of an illustrative antenna tuning element based on a variable inductor in accordance with an embodiment of the present invention.

FIG. 21 is a diagram of an illustrative antenna tuning element based on a switch-based adjustable load circuitry in accordance with an embodiment of the present invention.

FIG. 22 is a flow chart of illustrative steps for characterizing antenna structures under test using a test system with an auxiliary test structure in accordance with an embodiment of the present invention.

### DETAILED DESCRIPTION

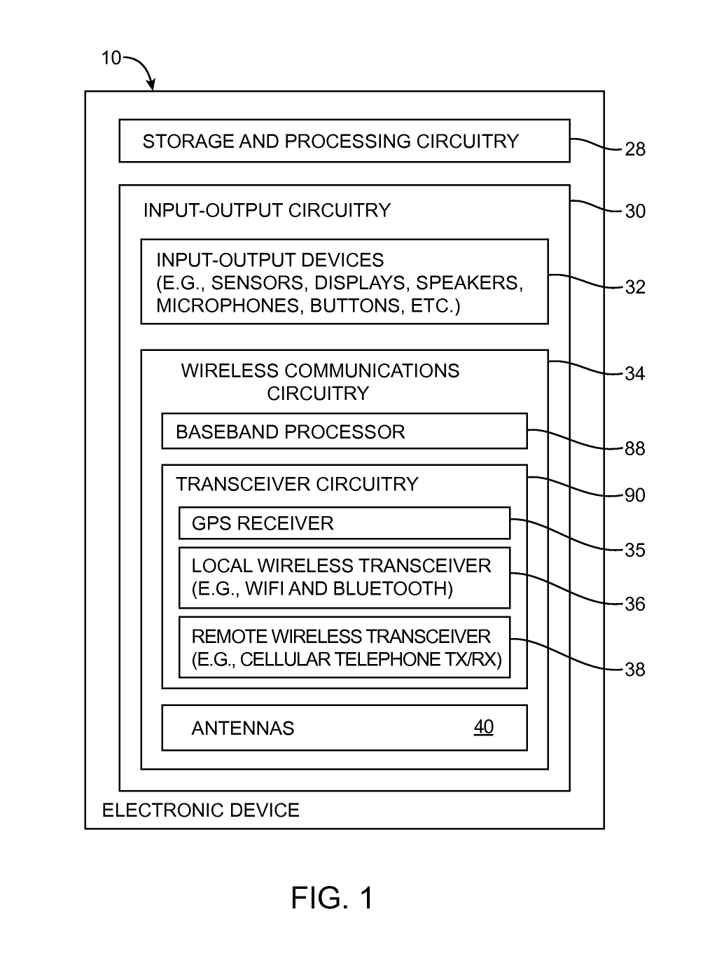

Electronic devices such as electronic device 10 of FIG. 1 may be provided with wireless communications circuitry. The wireless communications circuitry may be used to support wireless communications in multiple wireless communications bands. The wireless communications circuitry may include one or more antennas.

The antennas can include loop antennas, inverted-F antennas, strip antennas, planar inverted-F antennas, slot antennas, hybrid antennas that include antenna structures of more than one type, or other suitable antennas. Conductive structures for the antennas may, if desired, be formed from conductive electronic device structures. The conductive electronic device structures may include conductive housing structures. The housing structures may include a peripheral conductive member that runs around the periphery of an electronic device. The peripheral conductive member may serve as a bezel for a planar structure such as a display, may serve as sidewall structures for a device housing, and/or may form other housing structures. Gaps in the peripheral conductive member may be associated with the antennas.

Electronic device 10 may be a portable electronic device or other suitable electronic device. For example, electronic device 10 may be a laptop computer, a tablet computer, a somewhat smaller device such as a wrist-watch device, pendant device, headphone device, earpiece device, or other wearable or miniature device, a cellular telephone, or a media player. Device 10 may also be a television, a set-top box, a desktop computer, a computer monitor into which a computer has been integrated, or other suitable electronic equipment.

As shown in the schematic diagram of FIG. 1, electronic device 10 may include storage and processing circuitry 28. Storage and processing circuitry 28 may include storage such as hard disk drive storage, nonvolatile memory (e.g., flash memory or other electrically-programmable-read-only memory configured to form a solid state drive), volatile memory (e.g., static or dynamic random-access-memory), etc. Processing circuitry in storage and processing circuitry 28 may be used to control the operation of device 10. The processing circuitry may be based on one or more microprocessors, microcontrollers, digital signal processors, baseband processors, power management units, audio codec chips, application specific integrated circuits, etc.

Storage and processing circuitry 28 may be used to run software on device 10, such as internet browsing applications, voice-over-internet-protocol (VOIP) telephone call applications, email applications, media playback applications, operating system functions, etc. To support interactions with external equipment, storage and processing circuitry 28 may be used in implementing communications protocols. Communications protocols that may be implemented using storage and processing circuitry 28 include internet protocols, wireless local area network protocols (e.g., IEEE 802.11 protocols—sometimes referred to as WiFi®), protocols for other short-range wireless communications links such as the Bluetooth° protocol, cellular telephone protocols, etc.

Circuitry 28 may be configured to implement control algorithms that control the use of antennas in device 10. For example, circuitry 28 may perform signal quality monitoring operations, sensor monitoring operations, and other data gathering operations and may, in response to the gathered data and information on which communications bands are to be used in device 10, control which antenna structures within device 10 are being used to receive and process data and/or may adjust one or more switches, tunable elements, or other adjustable circuits in device 10 to adjust antenna performance. As an example, circuitry 28 may control which of two or more antennas is being used to receive incoming radio-frequency signals, may control which of two or more antennas is being used to transmit radio-frequency signals, may control the process of routing incoming data streams over two or more antennas in device 10 in parallel, may tune an antenna to cover a desired communications band, etc. In performing these control operations, circuitry 28 may open and close switches, may turn on and off receivers and transmitters, may adjust impedance matching circuits, may configure switches in front-end-module (FEM) radio-frequency circuits that are interposed between radio-frequency transceiver circuitry and antenna structures (e.g., filtering and switching circuits used for impedance matching and signal routing), may adjust switches, tunable circuits, and other adjustable circuit elements that are formed as part of an antenna or that are coupled to an antenna or a signal path associated with an antenna, and may otherwise control and adjust the components of device 10.

Input-output circuitry 30 may be used to allow data to be supplied to device 10 and to allow data to be provided from device 10 to external devices. Input-output circuitry 30 may include input-output devices 32. Input-output devices 32 may include touch screens, buttons, joysticks, click wheels, scrolling wheels, touch pads, key pads, keyboards, microphones, speakers, tone generators, vibrators, cameras, sensors, light-emitting diodes and other status indicators, data ports, etc. A user can control the operation of device 10 by supplying commands through input-output devices 32 and may receive status information and other output from device 10 using the output resources of input-output devices 32.

Wireless communications circuitry 34 may include radio-frequency (RF) transceiver circuitry formed from one or more integrated circuits, power amplifier circuitry, low-noise input amplifiers, passive RF components, one or more antennas, and other circuitry for handling RF wireless signals. Wireless signals can also be sent using light (e.g., using infrared communications).

Wireless communications circuitry 34 may include satellite navigation system receiver circuitry such as Global Positioning System (GPS) receiver circuitry 35 (e.g., for receiving satellite positioning signals at 1575 MHz) or satellite navigation system receiver circuitry associated with other satellite navigation systems. Transceiver circuitry 36 may handle 2.4 GHz and 5 GHz bands for WiFi® (IEEE 802.11) communications and may handle the 2.4 GHz Bluetooth° communications band. Circuitry 34 may use cellular telephone transceiver circuitry 38 for handling wireless communications in cellular telephone bands such as bands in frequency ranges of about 700 MHz to about 2200 MHz or bands at higher or lower frequencies. Wireless communications circuitry 34 can include circuitry for other short-range and long-range wireless links if desired. For example, wireless communications circuitry 34 may include wireless circuitry for receiving radio and television signals, paging circuits, etc. In WiFi® and Bluetooth° links and other short-range wireless links, wireless signals are typically used to convey data over tens or hundreds of feet. In cellular telephone links and other long-range links, wireless signals are typically used to convey data over thousands of feet or miles.

Wireless communications circuitry 34 may include one or more antennas 40. Antennas 40 may be formed using any suitable antenna types. For example, antennas 40 may include antennas with resonating elements that are formed from loop antenna structure, patch antenna structures, inverted-F antenna structures, closed and open slot antenna structures, planar inverted-F antenna structures, helical antenna structures, strip antennas, monopoles, dipoles, hybrids of these designs, etc. Different types of antennas may be used for different bands and combinations of bands. For example, one type of antenna may be used in forming a local wireless link antenna and another type of antenna may be used in forming a remote wireless link.

If desired, one or more of antennas 40 may be provided with multiple antenna feeds and/or adjustable components. Antennas such as these may be used to cover desired communications bands of interest. For example, a first antenna feed may be associated with a first set of communications frequencies and a second antenna feed may be associated with a second set of communications frequencies. The use of multiple feeds (and/or adjustable antenna components) may make it possible to reduce antenna size (volume) within device 10 while satisfactorily covering desired communications bands.

It may be desirable to test individual components in device 10 prior to actually assembling the components within device 10. Testing parts prior to assembly can help identify (at an early stage) potentially problematic issues that can negatively affect the performance of device 10 during normal user operation. For example, it may be desirable to characterize structures associated with antennas 40, because the integrity of these structures can often impact the antenna/wireless performance of device 10. Such types of structures that can potentially impact the radio-frequency performance of device 10 are sometimes referred to as antenna structures under test. Examples of antenna structures under test that may be characterized prior to being assembled within device 10 include conductive housing structures (e.g., conductive housing structures that form part of antennas 40), antenna feed structures (e.g., flexible antenna circuits, shorting pins, radio-frequency cables, etc.), radio-frequency amplifying circuit such as power amplifier and low noise amplifiers, matching circuits, filters, and other structural components of antennas 40.

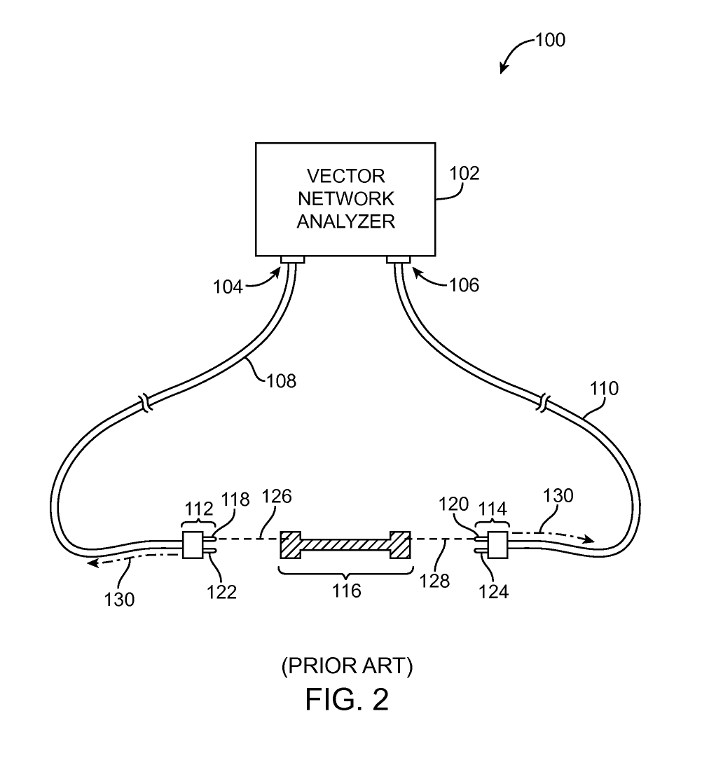

In the unassembled state, some of these antenna structures under test may not be readily tested. FIG. 2 is a diagram of a conventional test system 100 for characterizing a conductive pin 116. Test system 100 includes a vector network analyzer 102 having first test port 104 and second test port 106. First test probe 112 is connected to the first test port 104 via coaxial cable 108, whereas second test probe 114 is connected to second test port 106 via coaxial cable 110. First test probe 112 includes a signal pin 118 and a ground pin 122. Second test probe 114 includes a signal pin 120 and a ground pin 124.

During test operations, signal pin 118 of test probe 112 is mated with a first end portion of pin 116 (as shown by dotted line 126) while signal pin 120 of test probe 114 is mated with a second end portion of pin 116 (as shown by dotted line 128). Ground pins 122 and 124 of test probes 112 and 114, however, are not connected to pin 116. If ground pins 122 and 124 are not properly terminated, common mode noise current may be generated in the direction of arrows 130. Noise current generated in this way can undesirably reduce the accuracy of test results.

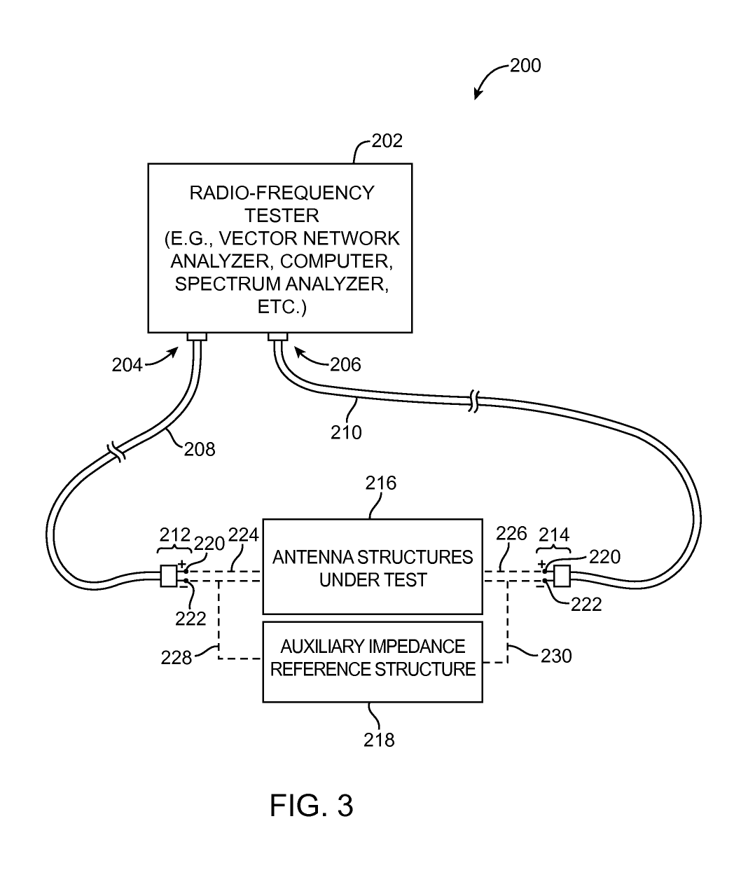

FIG. 3 is a diagram of an improved test system such as radio-frequency test system 200 (sometimes referred to as a test station) for use in characterizing antenna structures under test 216. As shown in FIG. 3, test system 200 may include a radio-frequency tester such as tester 202 and an auxiliary test structure such as structure 218. Radio-frequency tester 202 may include a computer, a vector network analyzer, a spectrum analyzer, a signal generator, and/or other radio-frequency test equipment suitable for transmitting/receiving radio-frequency test signals and obtaining/storing radio-frequency test measurements.

Tester 202 may have at least first and second test ports 204 and 206. First test port 204 may be coupled to a first test probe 212 via radio-frequency test cable 208. Second test port 206 may be coupled to a second test probe 214 via radio-frequency test cable 210. Radio-frequency cables 208 and 210 may be coaxial cables. For example, cable 208 may have an inner signal conductor that is electrically connected to corresponding signal contact pin 220 of test probe 212 and an outer ground conductor surrounding the inner signal conductor that is electrically connected to corresponding ground contact pin 222 of test probe 212. Similarly, cable 210 may have an inner signal conductor that is electrically connected to corresponding signal contact pin 220 of test probe 214 and an outer ground conductor surrounding the inner signal conductor that is electrically connected to corresponding ground contact pin 222 of test probe 214.

Test system 200 may be used to test antenna structures under test 216 in the unassembled state (i.e., before antenna structures 216 are assembled within device 10). Antenna structures under test 216 may be attached to auxiliary test structure 218 during test operations (e.g., antenna structures under test 216 may be mounted on auxiliary test structure 218). During testing, signal pins 220 of test probes 212 and 214 may be placed in contact with suitable test points on antenna structures under test 216 (as indicated by dotted lines 224 and 226). Ground pin 222 of test probe 212 may be configured to mate with a first corresponding ground contact region on antenna structures under test 216 or, if a ground contact region is absent on structures 216, with a first corresponding ground contact point on auxiliary test structure 218. Ground pin 222 of test probe 214 may be configured to mate with a second corresponding ground contact region on antenna structures under test 216 or, if a ground contact region is absent on structures 216, with a second corresponding ground contact point on auxiliary test structure 218.

Auxiliary test structure 218 may therefore serve to provide ground contact points for test probes 212 and 214 so that the interface between antenna structures under test 216 and the test equipment is properly terminated (e.g., so that the test probes are properly terminated to 50 ohms). Test structure 218 may therefore sometimes be referred to as an auxiliary impedance reference structure or an impedance reference test fixture. The example of FIG. 3 in which structure 218 supports testing with two test probes is merely illustrative. If desired, structure 218 may be configured to support characterization of antenna structures under test 216 with more than two test probes, with more than three test probes, with more than four test probes, etc.

During testing, tester 202 may be configured to produce radio-frequency test signals that are applied to device structures under test 216 using cables 208 and 210 and probes 212 and 214. Even without being connected to other components to form a completed antenna assembly for device 10, device structures under test 216 may emit wireless radio-frequency signals when driven using the test signals from the test probes. As test electromagnetic signals are transmitted by tester 202 and applied to device structures under test 216 through test probe 212, corresponding transmitted wireless electromagnetic test signals may be received through test probe 214 (as an example). Tester 202 may also receive reflected signals from cable 208 (i.e., signals that were reflected from device structures under test 216 in response to the signals transmitted through probe 212).

The transmitted and reflected signals gathered in this way may be used to compute a reflection coefficient (sometimes referred to as an S11 parameter or S11 scattering parameter). The transmitted signals on cable 208 and corresponding received signals on cable 210 may be used to compute a forward transfer coefficient (sometimes referred to as an S21 parameter or S21 scattering parameter). The S11 and S21 data may include magnitude and phase components.

During testing, S11 data and/or S21 data gathered using test equipment 202 may be compared to predetermined reference levels to determine whether antenna structures under test 216 satisfy design criteria. If the gathered data substantially matches the predetermined reference levels, test equipment 202 may inform an operator that device structures under test 216 are satisfactory or may take other suitable action. If the gathered data deviates from the reference data by more than an acceptable amount, test equipment 202 may inform the operator that device structures under test 216 include a fault and should be reworked or scrapped or may take other suitable action.

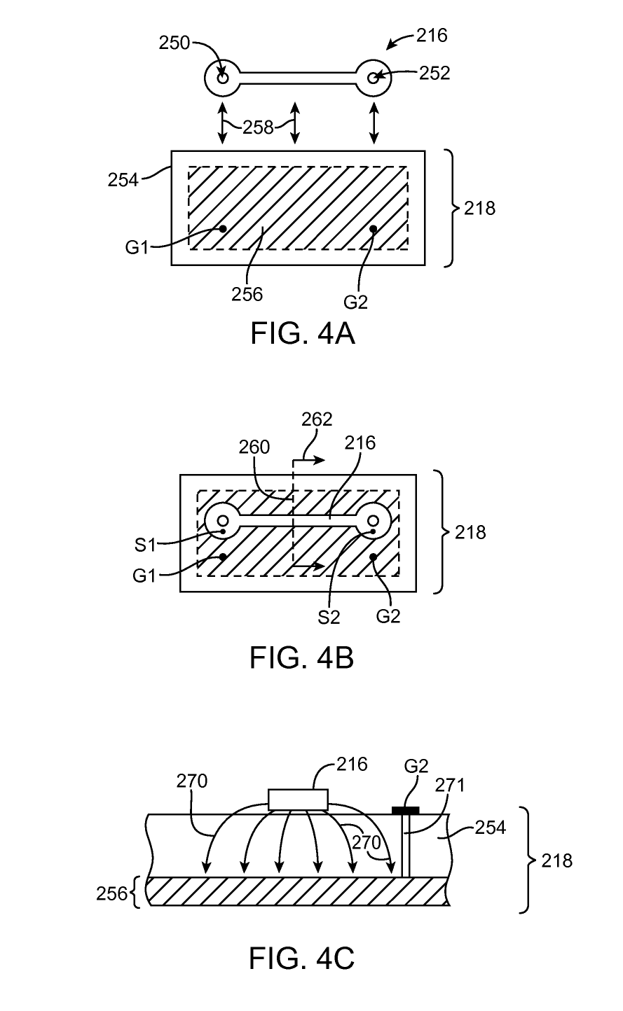

FIG. 4A shows a top view of an exemplary auxiliary test structure 218 on which an antenna structure under test such as a conductive shorting pin 216 may be mounted during testing. Shorting pin 216 may have a first terminal portion having a first through hole 250 and a second terminal portion having a second through hole 252. Shorting pin 216 may, for example, be attached to other housing structures within device 10 during device assembly by inserting screws into holes 250 and 252.

Auxiliary test structure 218 that is configured to receive shorting pin 216 of FIG. 4A may include substrate 254 having a top surface that is sufficiently large to accommodate pin 216 resting on its top surface. Substrate 254 may be a printed circuit board (PCB), as an example. Auxiliary test fixture 218 may have a ground plane 256 that is formed on a bottom surface of substrate 254. If desired, ground plane 256 may be formed in a layer within substrate 254 that is between the top and bottom surfaces. A first ground contact point G1 and a second ground contact point G2 may be formed on the top surface of substrate 254 (e.g., ground contact points G1 and G2 may include conductive pads that are formed on the top surface of substrate 254 and that are electrically shorted to ground plane 256 through conductive vias in substrate 254).

During testing, pin 216 may be temporarily placed on top of test fixture 218 (see, arrows 258). FIG. 4B shows a top view of pin 216 that is placed on top of auxiliary test fixture 218. The signal (+) and ground (−) pins of first test probe 212 may be placed in physical contact with signal contact point S1 on first terminal portion of pin 216 and ground contact point G1 on structure 218, respectively. The signal and ground pins of second test probe 214 may be placed in physical contact with signal contact point S2 on second terminal portion of pin 216 and ground contact point G2 on structure 218, respectively. Test probes that are mated to pin 216 and auxiliary test fixture 218 using this configuration may be properly terminated.

FIG. 4C shows a cross-sectional side view of FIG. 4B cut along line 260 and viewed in the direction of arrow 262. As shown in FIG. 4C, ground contact G2 may be coupled to ground reference plane 265 through substrate via 271 (as an example). When signals travel through pin 216, electric field lines 270 may originate from pin 216 and terminate at ground reference plane 256. This arrangement in which antenna structure under test 216 (i.e., the shorting pin) is attached to test structure 218 forms a microstrip transmission line structure through which radio-frequency test signals may be conveyed. In general, auxiliary test structure 218 may be configured to form any suitable transmission line path such as stripline transmission lines, edge coupled microstrip transmission lines, edge coupled stripline transmission lines, or other suitable transmission line structures through which radio-frequency test signals may be conveyed when antenna structures under test 216 are attached to fixture 218.

In wireless electronic devices requiring smaller form factor, one or more of antennas 40 may be provided with multiple antenna feeds and/or adjustable components. Antennas such as these may be used to cover desired communications bands of interest. For example, a first antenna feed may be associated with a first set of communications frequencies and a second antenna feed may be associated with a second set of communications frequencies. The use of multiple feeds (and/or adjustable antenna components) may make it possible to reduce antenna size (volume) within device 10 while satisfactorily covering desired communications bands. In one suitable embodiment of the present invention, the antenna feed structures (e.g., structures on which multiple antenna feeds are formed) may be characterized using test system 200 prior to being assembled within device 10. Because the antenna feed structures and the radio-frequency circuits mounted on the antenna feed structures are interposed in the transmit/receive path linking antenna 40 to wireless transceiver circuitry 90, the accuracy with which these components are manufactured may directly impact antenna performance.

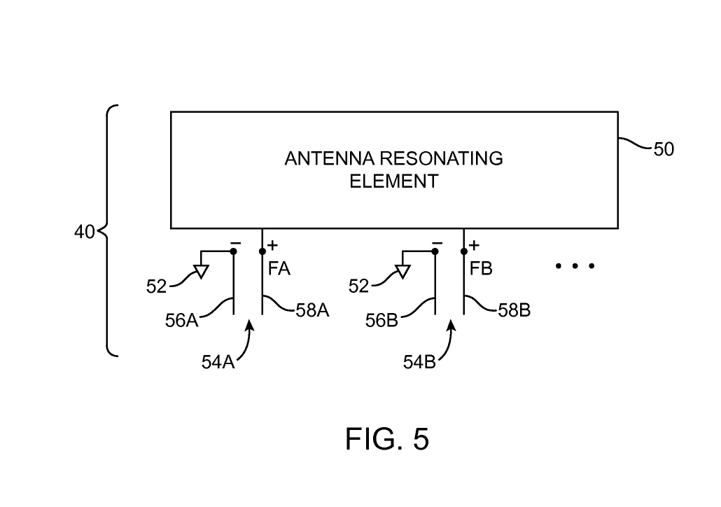

An illustrative configuration for an antenna with multiple feeds of the type that may be used in implementing one or more antennas for device 10 is shown in FIG. 5. As shown in FIG. 5, antenna 40 may have conductive antenna structures such as antenna resonating element 50 and antenna ground 52. The conductive structures that form antenna resonating element 50 and antenna ground 52 may be formed from parts of conductive housing structures, from parts of electrical device components in device 10, from printed circuit board traces, from strips of conductor such as strips of wire and metal foil, or other conductive materials. Antenna resonating element 50 may be coupled to transceiver circuitry 90 via antenna feed structures. When the antenna feed structures are not assembled within device 10, the antenna feed structures may not include antenna ground 52 (which is formed from part of the conductive device housing structures) and may therefore lack a ground reference plane during testing. It may therefore be desirable to be able to provide antenna structures under test such as antenna feed structures with a ground reference plane during testing using auxiliary reference test structure 218 (see, e.g., FIG. 3).

Each antenna feed associated with antenna 40 may, if desired, have a distinct location. As shown in FIG. 5, antenna 40 may have a first feed such as feed FA at a first location in antenna 40, a second feed such as feed FB at a second location in antenna 40, and one or more additional antenna feeds at potentially different respective locations of antenna 40.

Each feed may be coupled to an associated set of conductive signal paths using terminals such as antenna signal feed terminals (+) and antenna ground antenna terminals (−). For example, path 54A may have a positive conductor 58A that is coupled to a positive antenna feed terminal in feed FA and a ground conductor 56A that is coupled to a ground antenna feed terminal in feed FA, whereas path 54B may have a positive conductor 58B that is coupled to a positive antenna feed terminal in feed FB and a ground conductor 56B that is coupled to a ground antenna feed terminal in feed FB. Paths such as paths 54A and 54B may be implemented using transmission line structures such as coaxial cables, microstrip transmission lines (e.g., microstrip transmission lines on printed circuits), stripline transmission lines (e.g., stripline transmission lines on printed circuits), or other transmission lines or signal paths. Circuits such as impedance matching circuits, filter circuits, and other circuitry may be interposed within paths 54A and 54B.

The conductive structures that form antenna resonating element 50 and antenna ground 52 may be used to form any suitable type of antenna.

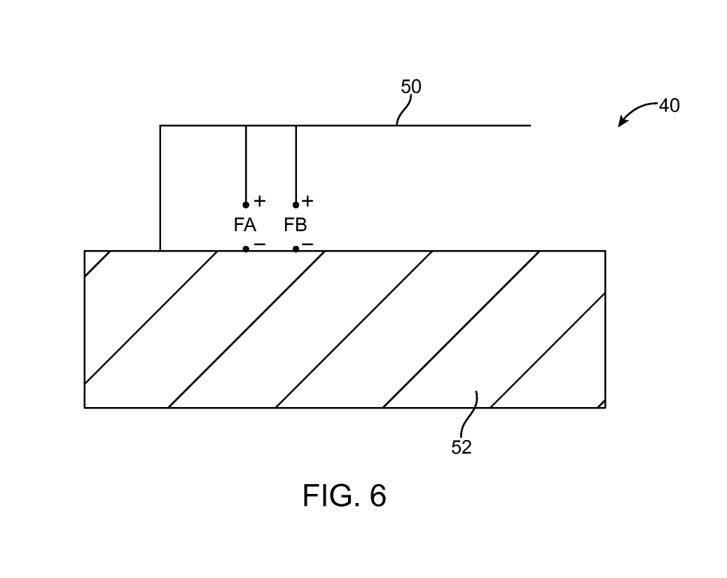

In the illustrative configuration of FIG. 6, antenna 40 has been implemented using an inverted-F antenna design. Inverted-F antenna 40 of FIG. 6 has a first antenna feed (feed FA with a corresponding positive terminal and ground terminal) and has a second antenna feed (feed FB with a corresponding positive terminal and ground terminal). Feeds FA and FB may be located at different respective locations along the length of the main resonating element arm that forms inverted-F antenna 40. Inverted-F configurations with multiple arms or arms of different shapes may be used, if desired.

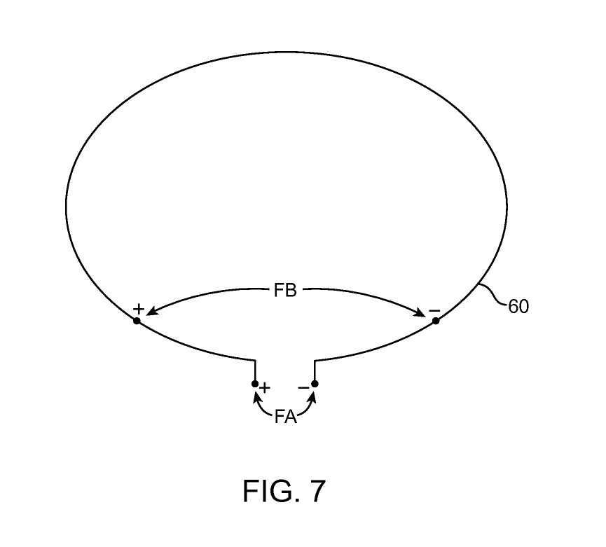

FIG. 7 is a diagram showing how antenna 40 may be implemented using a loop antenna configuration with multiple antenna feeds. As shown in FIG. 7, antenna 40 may have a loop of conductive material such as loop 60. Loop 60 may be formed from conductive structures 50 and/or conductive structures 52 (FIG. 5). A first antenna feed such as feed FA may have a positive antenna feed terminal (+) and a ground antenna feed terminal (−) and may be used to feed one portion of loop 60 and a second antenna feed such as feed FB may have a positive antenna feed terminal (+) and a ground antenna feed terminal (−) and may be used to feed antenna 40 at a different portion of loop 60.

The illustrative examples of FIGS. 6 and 7 are merely illustrative. Antenna 40 may, in general, have any suitable number of antenna feeds and may be formed using any suitable type of antenna structures.

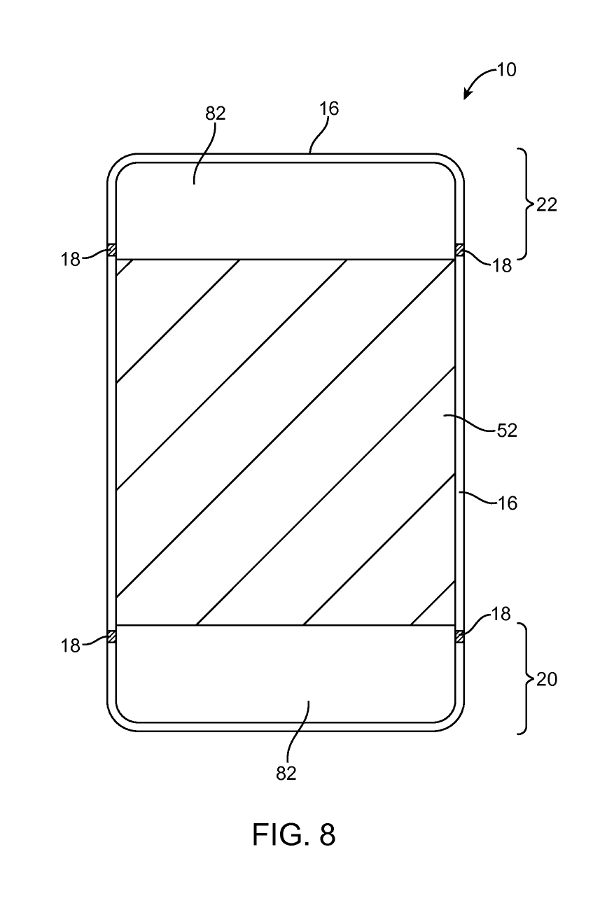

A top interior view of device 10 in a configuration in which device 10 has a peripheral conductive housing member such as housing member 16 with one or more gaps 18 is shown in FIG. 8. As shown in FIG. 8, device 10 may have an antenna ground plane such as antenna ground plane 52. Ground plane 52 may be formed from traces on printed circuit boards (e.g., rigid printed circuit boards and flexible printed circuit boards), from conductive planar support structures in the interior of device 10, from conductive structures that form exterior parts of a device housing, from conductive structures that are part of one or more electrical components in device 10 (e.g., parts of connectors, switches, cameras, speakers, microphones, displays, buttons, etc.), or other conductive device structures. Gaps such as gaps 82 may be filled with air, plastic, or other dielectric.

One or more segments of peripheral conductive member 16 may serve as antenna resonating elements such as antenna resonating element 50 of FIG. 5. For example, the uppermost segment of peripheral conductive member 16 in region 22 may serve as an antenna resonating element for an antenna in device 10. The conductive materials of peripheral conductive member 16, the conductive materials of ground plane 52, and dielectric openings 82 (and gaps 18) may be used in forming one or more antennas in device 10 such as an upper antenna in region 22 and a lower antenna in region 20. Configurations in which an antenna in upper region 22 is implemented using a dual feed arrangement are sometimes described herein as an example.

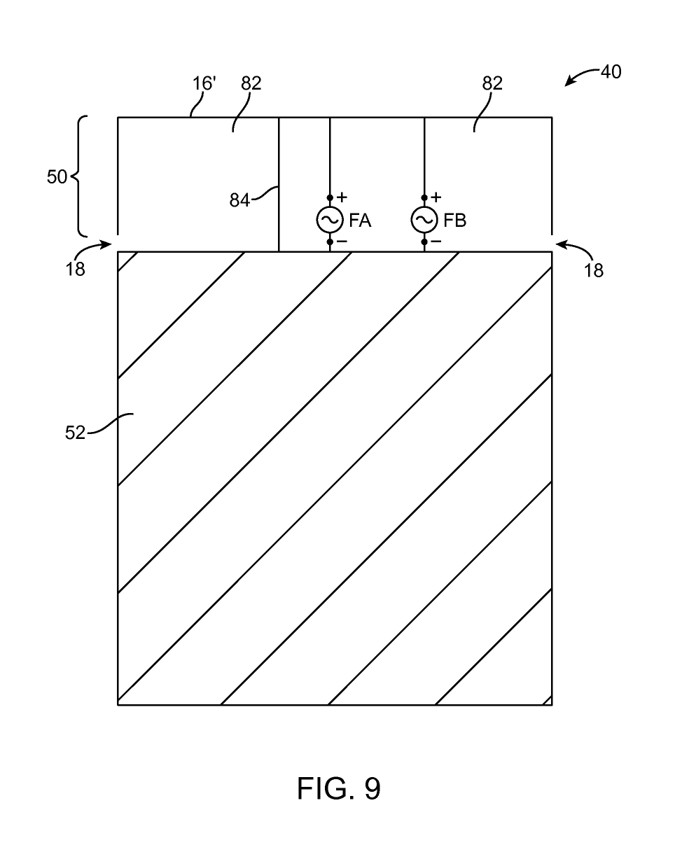

Using a device configuration of the type shown in FIG. 9, a dual-feed antenna such as antenna 40 of FIG. 9 may be implemented (e.g., a dual-feed inverted-F antenna). Segment 16′ of the peripheral conductive member (see, e.g., peripheral conductive member 16 of FIG. 8) may form antenna resonating element 50. Ground plane 52 may be separated from antenna resonating element 50 by gap 82. Gaps 18 may be formed at either end of segment 16′ and may have associated parasitic capacitances. Conductive path 84 may form a short circuit path between antenna resonating element (i.e., segment 16′) and ground 52. First antenna feed FA and second antenna feed FB may be located at different locations along the length of antenna resonating element 50.

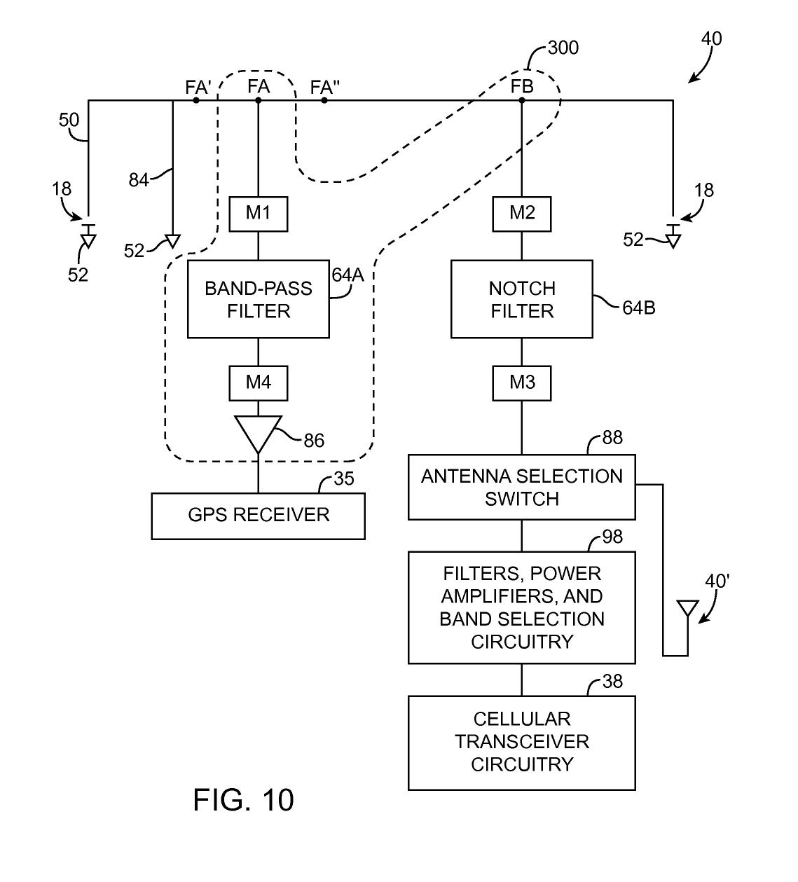

As shown in FIG. 10, it may be desirable to provide each of the feeds of antenna 40 with filter circuitry and impedance matching circuitry. In a configuration of the type shown in FIG. 10, antenna resonating element 50 may be formed from a segment of peripheral conductive member 16 (e.g., segment 16′ of FIG. 9). Antenna ground 52 may be formed from ground plane structures such as ground plane structure 52 of FIG. 8. Antenna 40 of FIG. 10 may be, for example, an upper antenna in region 22 of device 10 (e.g., an inverted-F antenna). Device 10 may also have additional antennas such as antenna 40′ (e.g., an antenna formed in lower portion 20 of device 10, as shown in FIG. 8).

In the illustrative example of FIG. 10, satellite navigation receiver 35 (e.g., a Global Positioning System receiver or a receiver associated with another satellite navigation system) may serve as a first transceiver for device 10, whereas cellular telephone transceiver circuitry (e.g., a cellular telephone transmitter and a cellular telephone receiver) may serve as a second transceiver for device 10. If desired, other types of transceiver circuitry may be used in device 10. The example of FIG. 10 is merely illustrative.

As shown in FIG. 10, receiver 35 may be coupled to antenna 40 at first antenna feed FA and transceiver 38 may be coupled to antenna 40 at second antenna feed FB.

Incoming signals for receiver 35 may be received through band-pass filter 64A, optional impedance matching circuits such as matching circuits M1 and M4, and low noise amplifier 86 (e.g., the signals received from feed FA may be conveyed through components such as matching filter M1, band-pass filter 64A, matching circuit M4, and low noise amplifier 86 using transmission lines paths such as transmission line path 54A of FIG. 5). Additional components may be interposed in transmission line path 54A, if desired.

Signals associated with transmit and receive operations for cellular transceiver circuitry 38 may be handled using notch filter 64B, optional impedance matching circuits such as matching circuits M2 and M3, antenna selection switch 88, and circuitry 98 (e.g., the components used in transmitting and receiving signals with feed FB may be conveyed through components such as matching filter M2, notch filter 64B, matching circuit M3, and circuitry 90 using transmission lines paths such as transmission line path 54B of FIG. 5). Additional components may be interposed in transmission line path 54B, if desired. Antenna selection switch 88 may have a first state in which antenna 40 is coupled to transceiver 38 and a second state in which antenna 40′ is coupled to transceiver 38 (as an example). If desired, switch 88 may be a cross-bar switch that couples either antenna 40 or antenna 40′ to transceiver 38 while coupling the remaining antenna to another transceiver. Circuitry 98 may include filters (e.g., duplexers, diplexers, etc.), power amplifier circuitry, band selection switches, and other radio-frequency components.

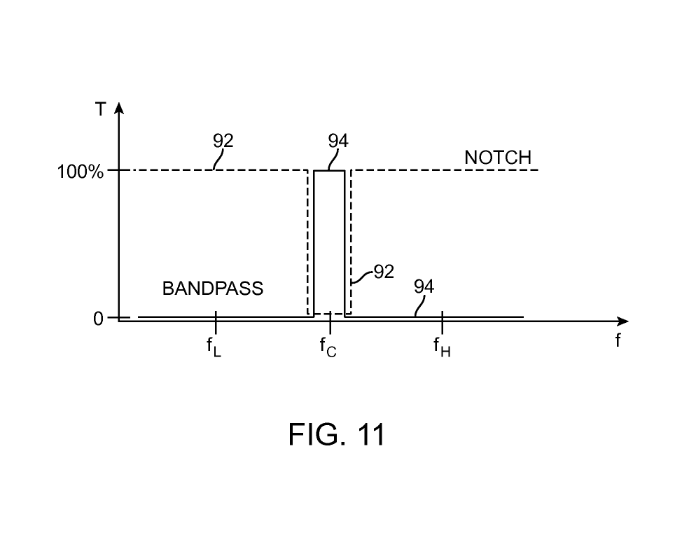

The transmission T that may be exhibited by notch filter 64B and band-pass filter 64A as a function of frequency f is shown in FIG. 11. In the graph of FIG. 11, the transmission of notch filter 64B is represented by the transmission characteristic of line 92, whereas the transmission of band-pass filter 64A is represented by the transmission characteristic of line 94. As indicated by line 94, band-pass filter 64A may pass signals with frequencies in a passband centered at frequency f_{C} and may block lower and higher frequencies such as frequencies f_{L} and f_{H}. As indicated by line 92, notch filter 64B may have a transmission characteristic that is complementary to that of band-pass filter 64A. In particular, notch filter 64B may block signals in a frequency band centered around frequency f_{C} while passing lower frequency signals in the vicinity of frequency f_{L} and while passing higher frequency signals in the vicinity of frequency f_{H} (i.e., notch filter 64B may have a stopband that overlaps the passband of band-pass filter 64A).

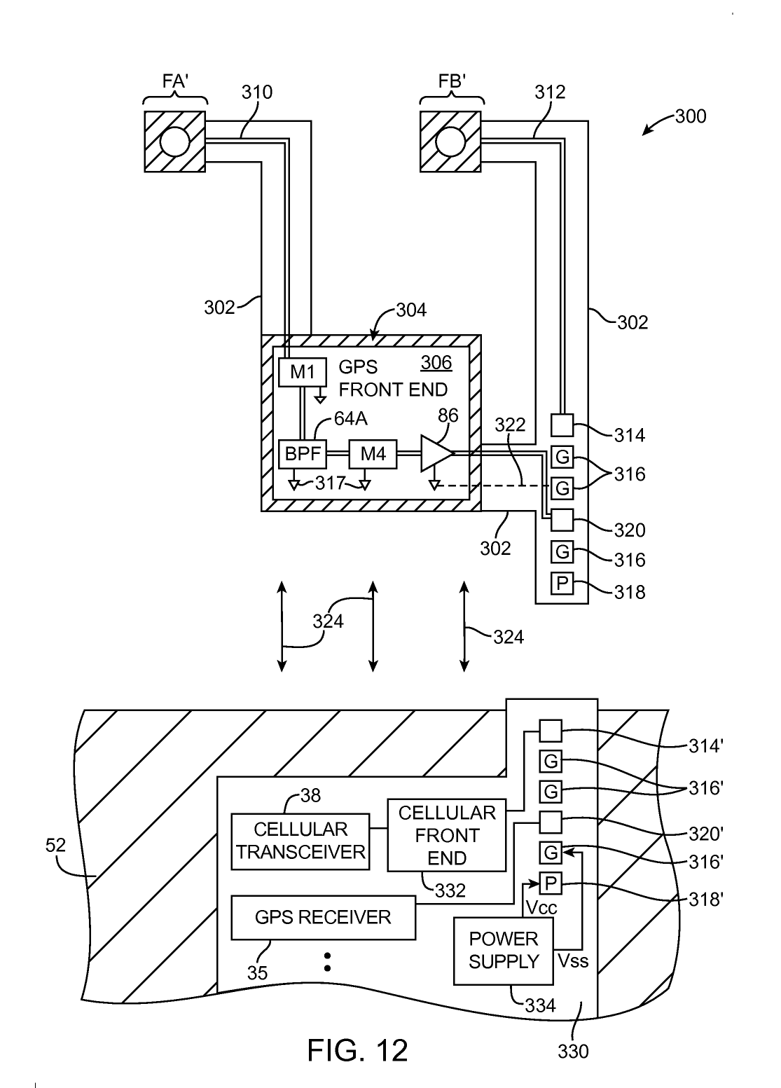

An antenna feed structure under test such as dual-feed structure 300 may include matching circuits M1 and M4, band-pass filter 64A, low noise amplifier 86, and antenna signal feed terminals associated with feeds FA and FB (see, e.g., FIG. 10 and FIG. 12). FIG. 12 is a diagram of an exemplary antenna feed structure 300 that may be tested using test system 200 of the type described in connection with FIG. 3. As shown in FIG. 12, antenna feed structure 300 may be formed using a flexible substrate such as flexible printed circuit board 302 (sometimes referred to as a “flex circuit”). Conductive pad structures such as pad structures 314, 316, 318, and 320 may be formed on substrate 302. In the example of FIG. 12, pad 314 may be coupled to signal feed terminal FB′ that is associated with antenna feed FB via signal trace 312 formed in substrate 302. Pad structure 320 may be coupled to signal feed terminal FA′ that is associated with antenna feed FA via signal trace 310 formed in substrate 302. Pad structures 316 may serve as ground contacts while pad structure 318 may serve as a positive power supply contact (e.g., pad structures 316 and 318 may collectively be used to supply power to active electrical components mounted on substrate 302).

A rigid substrate support member such as support member 304 may be formed as part of substrate 302. Support member 304 may be used to provide sufficient mechanical support so that active circuit components such as GPS front end circuitry 306 (e.g., matching circuits M1 and M4, filter 64A, and low noise amplifier 86) can be properly mounted and secured to antenna feed structure 300. Support member 304 may sometimes be referred to as a stiffener. The circuits in GPS front end circuitry 306 may each have a first power supply terminal that is coupled to pad 318 and a second power supply terminal that is coupled to pads 316 (see, e.g., dotted path 322). As an example, the second power supply terminal may be coupled to a ground plane 317 that is formed as a layer within support member 304. In one suitable embodiment of the present invention, ground plane 317 may be accessible from the underside of member 304 when member 304 is mounted over a corresponding fixture during testing.

Antenna feed structure 300 may be attached to another device structure such as substrate 330 that is formed over ground plane 52 (as indicated by arrows 324). Storage and processing circuitry 28, baseband processor 88, GPS receiver 35, cellular transceiver 38, cellular front end circuitry 332 (e.g., matching circuits M2 and M3, notch filter 64B, antenna selection switch 88, band selection circuitry 98, etc.), power supply circuitry 334 (e.g., a battery configured to supply power supply voltages Vcc and Vss), and other control circuitry may be formed on substrate 330. Substrate 330 may therefore sometimes be referred to as a main logic board (MLB).

Conductive pad structures 314′, 316′, 318′, and 320′ may also be formed on substrate 330. In particular, pad 314′ may be coupled to cellular transceiver 38 via cellular front end 332 and may be configured to mate with pad 314 on antenna feed structure 300. Pad 320′ may be coupled to GPS receiver 35 and may be configured to mate with pad 320 on antenna feed structure 300. Pads 318′ and 320′ may be coupled to power supply 334 and may be mated with pads 318 and 320 on antenna feed structure 330, respectively.

During device assembly operations, assembly personnel may mate antenna feed structure 300 with main logic board 330 (e.g., to connect the wireless transceiver circuitry to corresponding feed terminals FA′ and FB') and may mate antenna feed structure 300 to antennas 40 (e.g., to connect the antenna feed points to respective locations on antenna resonating element 50 (see, e.g., FIGS. 5-7, 9, and 10). Assembled in this way, wireless transceiver circuitry 90 may be coupled to antenna resonating element 50 via antenna feed structure 300.

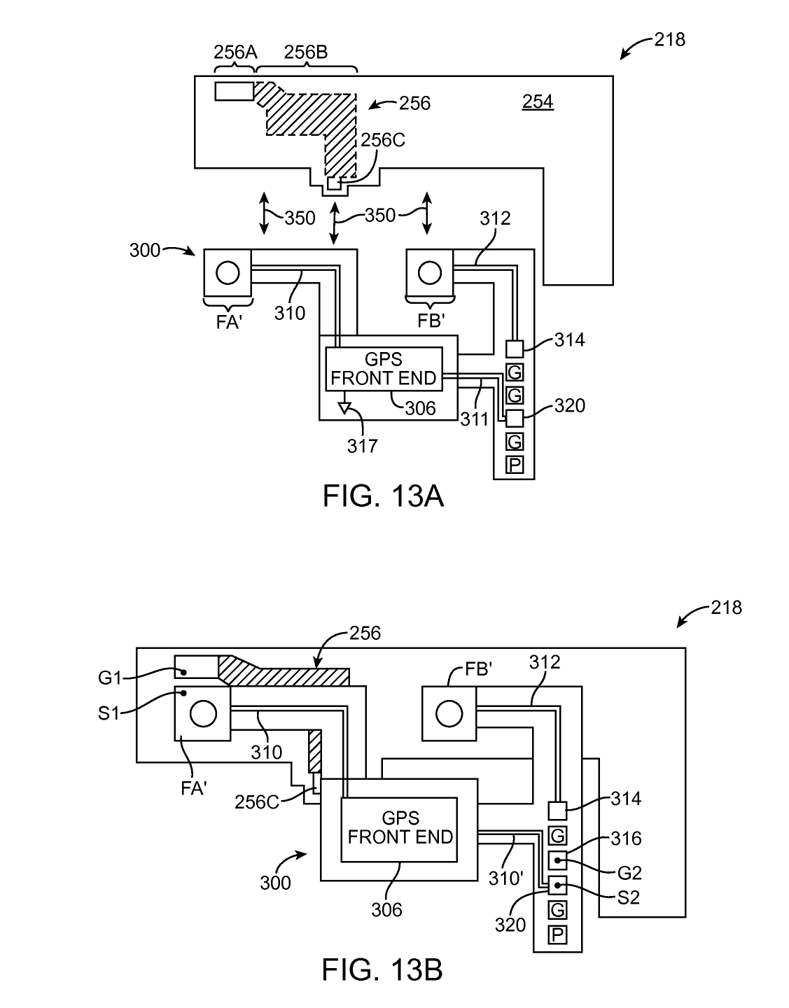

It may be desirable to test antenna feed structure 300 (e.g., to characterize the circuits mounted on structure 300) prior to device assembly. FIG. 13A shows a top view of an illustrative auxiliary test fixture 218 configured to receive antenna feed structure 300 during testing, as indicated by arrows 350. As shown in FIG. 13A, test fixture 218 may be formed from a substrate 254. Substrate 254 may be a rigid substrate or a flexible substrate (as examples). Auxiliary test structure 218 may have conductive regions 256A and 265C formed on a top surface of substrate 254 and a conductive region 256B formed on a bottom surface of substrate 254. Regions 256A and 256B may be electrically connected through vias within substrate 254. Similarly, regions 256C and 256B may be electrically connected through vias formed within substrate 254.

Antenna feed structure 300 may be mounted on test structure 218 during testing. In the mounted state (see, e.g., FIG. 13B), feed member FA′ that is coupled to conductive pad structure 320 via GPS front end and signal paths 310 and 310′ may be positioned adjacent to conductive region 256A of test structure 218. In the mounted state, region 256C may be coupled to ground reference 317 associated with GPS front end 306 so that current can flow from auxiliary structure 218 back into antenna structure under test 300 (e.g., to provide radio-frequency test signals with a return current path back into tester 202). Region 256C may be formed using a conductive pad, a conductive pin, or other suitable mechanisms for making an electrical connection with ground terminal 317. Arranged in this way, test reference structure 218 may therefore be used to provide a continuous ground reference plane between the test equipment and the circuits under test (e.g., GPS front end 306).

As shown in FIG. 13B, region 256B of test structure 218 may serve as a ground reference plane for signal path 310 (as long as ground plane 256B substantially overlaps the footprint of signal path 310). In this arrangement, feed member FA′ may serve as a first signal contact point S1 whereas conductive region 256A may serve as a first ground contact point G1. Pad structure 320 may serve as a second signal contact point S2 whereas ground pad 316 may serve as a second ground contact point G2. While antenna feed structure under test 300 is attached to test structure 218, first test probe 212 may be used to mate with signal and ground contact points S1 and G1, respectively, while second test probe 214 may be used to mate with signal and ground contact points S2 and G2, respectively (see, e.g., FIG. 3).

Providing a ground reference plane for signal path 310 in antenna structure under test 300 reduces impedance mismatch between the test probe and the antenna structures under test and helps to improve the accuracy of test results associated with the performance of GPS front end 306 (e.g., ground reference 256 in substrate 254 helps reduce test variance that may be caused as a result of common mode noise current associated with signal path 310 if ground plane reference 256 were absent). The example of FIGS. 13A and 13B in which auxiliary test structure 218 is configured to provide a ground reference plane for signal path 310 associated with feed FA is merely illustrative and does not serve to limit the scope of the present invention. If desired, auxiliary test structure 218 may also be configured to provide a ground reference plane for signal path 310′. In another suitable arrangement, auxiliary test structure 218 may be configured to facilitate testing of antenna feed terminal FB′ or other antenna feed structures with any suitable number of antenna feeds.

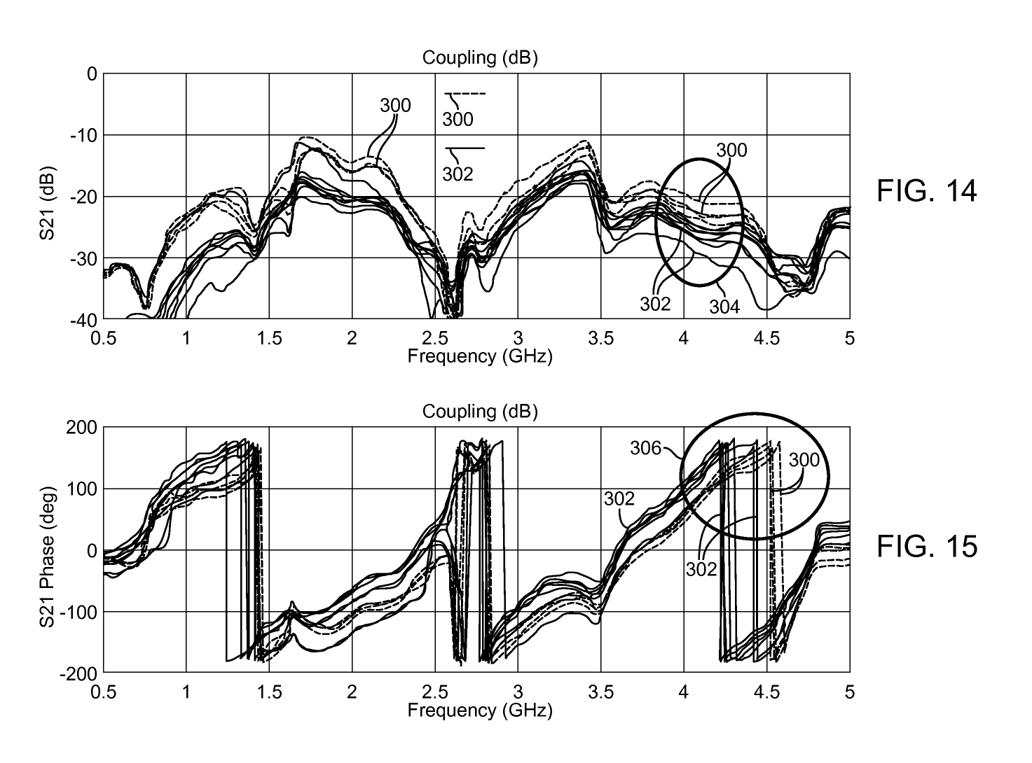

Illustrative test data gathered from a single antenna structure under test 300 using test system 200 of FIG. 3 is shown in FIGS. 14 and 15. In FIG. 14, the magnitude of forward transfer coefficient S21 has been plotted as a function of test signal frequency for a frequency range of 0 to 5 GHz. In FIG. 15, the phase of forward transfer coefficient S21 has been plotted as a function of test signal frequency for a frequency range of 0 to 5 GHz. There are two sets of curves in the graphs of FIGS. 14 and 15. Curves 302 correspond to test data for structure 300 that has been tested without the use of auxiliary test structure 218, whereas curves 300 correspond to test data for structure 300 that has been tested while being mounted on a corresponding auxiliary test structure 218. As indicated by illustrative frequency ranges 304 and 306 (e.g., about 3.5 to 5 GHz) in FIGS. 14 and 15, respectively, curves 302 exhibit more variation than curves 300. Testing antenna device structures using auxiliary reference test structure 218 may therefore yield more consistent and accurate test results. Other frequency ranges may be investigated if desired (e.g. a range of frequencies covering 1 to 5 GHz, a range of frequencies including frequencies between 2 and 4 GHz, etc.).

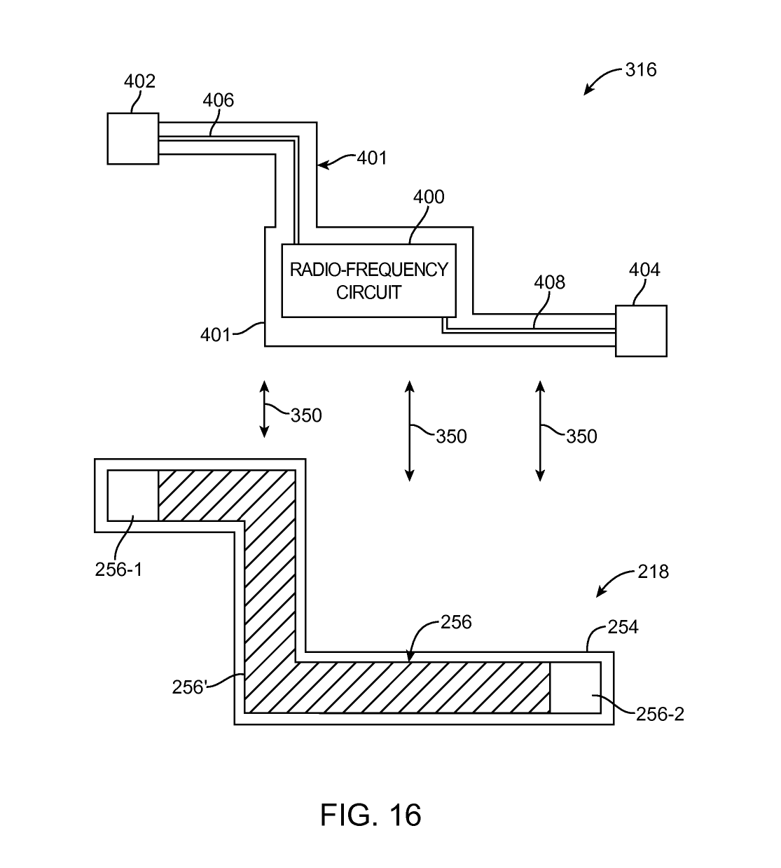

In general, auxiliary test structure 218 may be configured to receive any device structure under test (e.g., device structures under test that lack ground contact points). FIG. 16 shows an exemplary antenna structure under test 216 and its corresponding auxiliary test structure 218. Antenna structure under test 216 of FIG. 16 may include a radio-frequency circuit 400 that is mounted on a substrate 401 (e.g., a rigid printed circuit board, a flex circuit, etc.), where radio-frequency circuit 400 is coupled to a first contact member 402 via signal path 406 and is coupled to a second contact member 404 via signal path 408.

Antenna structure under test 216 may be placed on top of auxiliary test structure 218, as indicated by arrows 350. Test structure 218 may be formed from substrate 254. Test structure 218 may include ground reference planes 256 formed on top and bottom surfaces of substrate 254. For example, a first conductive grounding portion 256-1 and a second conductive grounding portion 256-2 may be formed on the top surface of substrate 254, whereas grounding portion 256′ may be formed on the bottom surface of substrate 254. During testing when antenna structure 216 is mounted on top of auxiliary test fixture 218, portion 256-1 may serve as an auxiliary ground probe point for first contact member 402 while portion 256-2 may serve as an auxiliary ground probe point for second contact member 404. Conductive portion 256′ may serve as a ground reference plane for signal paths 406 and 408 so that radio-frequency signals conveyed through paths 406 and 408 exhibit desirable behaviors.

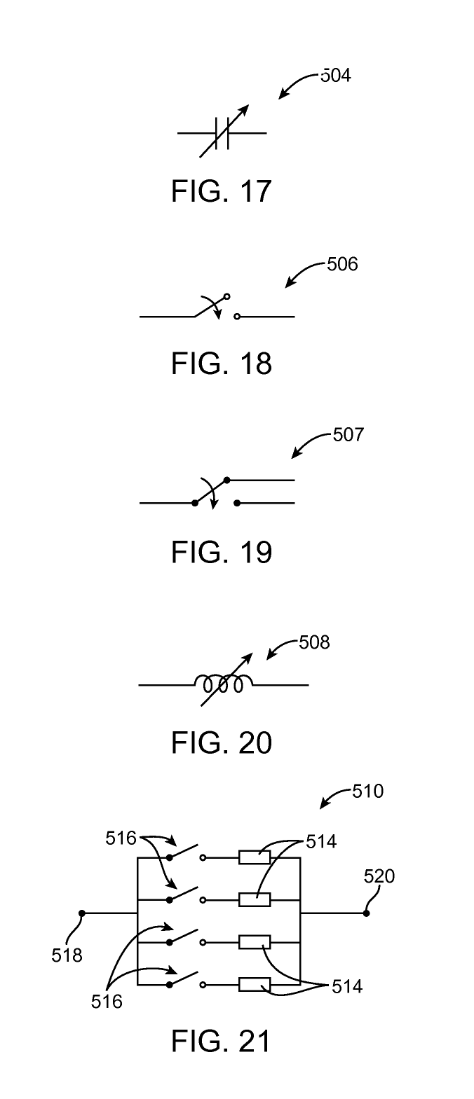

The performance of radio-frequency circuit 400 may be tested while a first test probe is mated to conductive members 402 and 256-1 and while a second test probe is mated to conductive members 404 and 256-2. Examples of radio-frequency circuits 400 that may be tested are shown in FIGS. 17, 18, 19, 20, and 21. Circuit 400 may include a tunable circuit such as a variable capacitor 504 of FIG. 17, a radio-frequency switch such as a single-pole, single-throw switch 506 of FIG. 18 or a single-pole, double-throw switch 507 of FIG. 19, a variable inductor such as variable inductor 508 of FIG. 20, adjustable load circuitry such as adjustable load circuitry 510 of FIG. 21, other adjustable components and combinations of two or more of such components (e.g., combinations of tunable and/or fixed components), filters, power amplifiers, low-noise amplifiers, matching circuits, and other suitable radio-frequency structures.

Adjustable load circuitry 510 of FIG. 21 may include an array of load circuits 514 (e.g., capacitors, inductors, resistors, etc.) and associated switches 516 for selectively switching one or more of circuits 514 into place between terminals 518 and 520. The states of switches 516 may be controlled by control signals from control circuitry in device 10 (e.g., a baseband processor in storage and processing circuitry 28 of FIG. 1). Load circuits 514 may be selectively coupled in parallel between terminals 518 and 520 as shown in FIG. 21. Other configurations for adjustable load circuitry 510 may be used, if desired. For example, configurations in which load circuits are connected in series and are provide with switch-based selective bypass paths may be used, configurations with combinations of parallel and series-connected load circuits 514 may be used, etc.

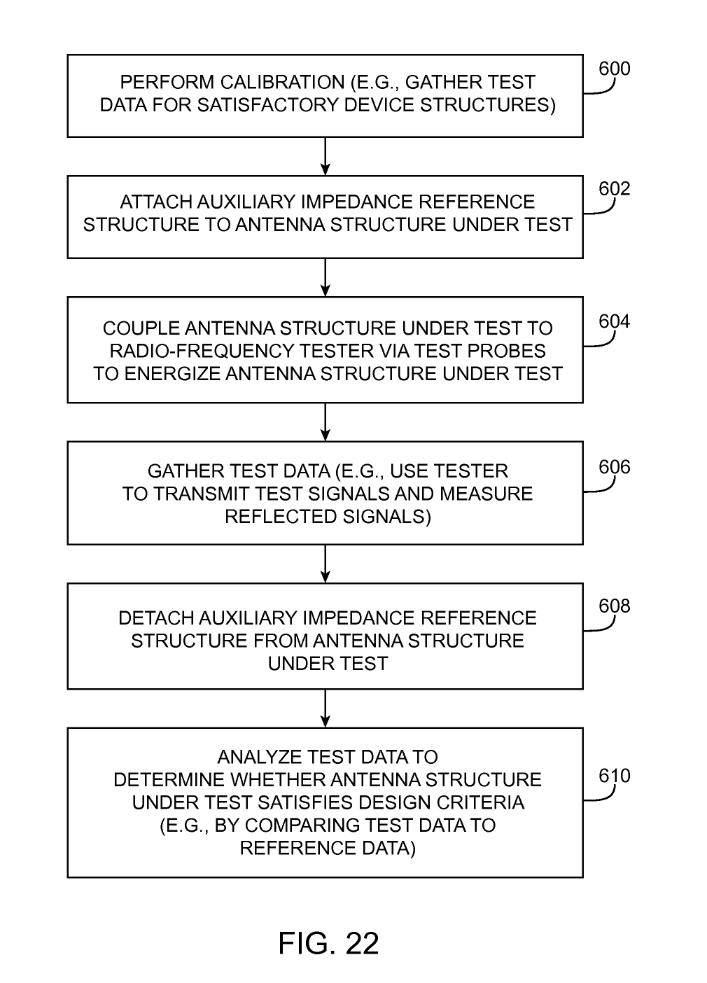

Illustrative steps involved in testing device structures under test 216 using a test system of the type shown in FIG. 200 are shown in FIG. 22. At step 600, calibration operations may be performed (e.g., baseline reference data may be gathered from satisfactory device structures or from “golden” reference device structures). At step 602, antenna structure under test 216 (or other device structures that form part of device 10) may be mounted on auxiliary reference test structure 218.

At step 604, antenna structure under test 216 may be coupled to radio-frequency test 202 via test probes 212 and 214 to energize antenna structure under test 216 (e.g., tester 202 may generate radio-frequency test signals that are applied to antenna structure under test 216 by mating the test probes to appropriate signal and ground contact points on structures 216 and 218). At step 606, test data may be gathered from antenna structure 216 currently under test by using tester 202 to transmit test signals and to receive corresponding reflected signals.

At step 608, antenna structure under test 216 may be detached from auxiliary test structure 218 so that auxiliary test structure 218 can receive a subsequent antenna structure under test in the production line. At step 610, a test host (e.g., a personal computer) may analyze the test data (e.g., by computing S11 and S12 parameters and comparing the computed results to the baseline reference data obtained during step 600) to determine whether antenna structure under test 216 satisfies design criteria. For example, if the measured test data substantially matches the reference data, antenna structure under test 216 may be marked as a passing component and may be assembled within device 10. If, however, the measured test data deviates from the reference data by more than a predetermined amount, antenna structure under test 216 may be marked as a failing component and may be reworked or scrapped.

The foregoing is merely illustrative of the principles of this invention and various modifications can be made by those skilled in the art without departing from the scope and spirit of the invention. The foregoing embodiments may be implemented individually or in any combination.

What is claimed is:

1. A method for using a test system to test an antenna structure under test, wherein the test system includes a test probe and an auxiliary test structure, the method comprising:
attaching the antenna structure under test to the auxiliary test structure; and
while the antenna structure under test is attached to the auxiliary test structure, mating the test probe with the antenna structure under test and the auxiliary test structure.

2. The method defined in claim 1, wherein mating the test probe with the antenna structure under test comprises using the test probe to contact the antenna structure under test and the auxiliary test structure.

3. The method defined in claim 1, wherein the test probe includes a first contact pin and a second contact pin, and wherein mating the test probe with the antenna structure under test and the auxiliary test structure comprises:
placing the first contact pin in contact with the antenna structure under test; and
placing the second contact pin in contact with the auxiliary test structure.

4. The method defined in claim 1, wherein the antenna structure under test includes a first contact member, wherein the auxiliary test structure includes a second contact member, wherein the test probe includes a first contact pin and a second contact pin, and wherein mating the test probe with the antenna structure under test and the auxiliary test structure comprises:
placing the first contact pin in contact with the first contact member on the antenna structure under test; and
placing the second contact pin in contact with the second contact member on the auxiliary test structure.

5. The method defined in claim 1, wherein attaching the antenna structure under test to the auxiliary test structure comprises mounting the antenna structure under test on top of the auxiliary test structure.

6. The method defined in claim 3, wherein the test system further includes a radio-frequency tester, the method further comprising:
while the test probe is mated with the antenna structure under test and the auxiliary test structure, using the radio-frequency tester to transmit radio-frequency test signals and to receive corresponding reflected signals via the first and second contact pins.

7. The method defined in claim 1, wherein the antenna structure under test includes a radio-frequency circuit under test, and wherein attaching the antenna structure under test to the auxiliary test structure comprises attaching the antenna structure under test to the auxiliary test structure so that a continuous ground reference is provided between the test probe and the circuit under test.

8. A method for using a test system to test a device structure under test having a signal trace formed on a first substrate, wherein the test system includes a radio-frequency tester and an auxiliary test structure having a ground plane formed on a second substrate, the method comprising:
mounting the device structure under test on the auxiliary test structure so that the ground plane on the second substrate is positioned beneath the signal trace on the first substrate; and
while the device structure under test is mounted on the auxiliary test structure, using the radio-frequency tester to generate radio-frequency test signals, wherein the radio-frequency test signals are fed through the signal trace.

9. The method defined in claim 8, wherein the test system further includes a test probe that is coupled to the radio-frequency tester via a radio-frequency cable, the method further comprising:
using the test probe to contact the device structure under test, wherein the radio-frequency test signals are conveyed from the radio-frequency tester to the device structure under test via the test probe.

10. The method defined in claim 9 further comprising:
using the test probe to contact the auxiliary test structure.

11. The method defined in claim 8 further comprising:
with the radio-frequency tester, gathering radio-frequency test measurements on the device structure under test, wherein the radio-frequency test measurements comprise reflection coefficient and forward transfer coefficient data.

12. The method defined in claim 8, wherein the second substrate has a top surface and a bottom surface, wherein the ground place is formed on the bottom surface of the second substrate, and wherein mounting the device structure under test on the auxiliary test structure comprises mounting the device structure on the top surface of the auxiliary test structure.

13. The method defined in claim 8, wherein the device structure under test comprises antenna structures, and wherein mounting the device structure under test on the auxiliary test structure comprises mounting the antenna structures on the auxiliary test structure.

14. The method defined in claim 9, wherein the device structure under test includes a radio-frequency circuit under test having a ground terminal, and wherein mounting the device structure under test on the auxiliary test structure comprises mounting the device structure under test on the auxiliary test structure so that the ground plane on the second substrate is electrically connected to the ground terminal of the radio-frequency circuit under test.

15. A method for using a test system to test a device structure under test having a signal trace coupled to a first contact member, wherein the test system includes a radio-frequency test probe having a signal pin and a ground pin and an auxiliary test structure having a second contact member, the method comprising:
mounting the device structure under test on the auxiliary test structure; and
while the device structure under test is mounted on the auxiliary test structure, mating the radio-frequency test probe with the device structure under test and the auxiliary test structure so that the signal pin is placed in contact with the first contact member and so that the ground pin is placed in contact with the second contact member.

16. The method defined in claim 15, wherein the device structure under test further includes a third contact member that is coupled to the signal trace and a fourth contact member that is associated with the third contact member, and wherein the test system includes an additional radio-frequency test probe having a signal pin and a ground pin, the method comprising:
while the device structure under test is mounted on the auxiliary test structure, mating the additional radio-frequency test probe with the device structure under test and the auxiliary test structure so that the signal pin of the additional radio-frequency test probe is placed in contact with the third contact member and so that the ground pin of the additional radio-frequency test probe is placed in contact with the fourth contact member.

17. The method defined in claim 15, wherein the device structure under test further includes a third contact member that is coupled to the signal trace, wherein the auxiliary test structure further includes a fourth contact member that is electrically coupled to the second contact member, and wherein the test system includes an additional radio-frequency test probe having a signal pin and a ground pin, the method comprising:
while the device structure under test is mounted on the auxiliary test structure, mating the additional radio-frequency test probe with the device structure under test and the auxiliary test structure so that the signal pin of the additional radio-frequency test probe is placed in contact with the third contact member and so that the ground pin of the additional radio-frequency test probe is placed in contact with the fourth contact member.

18. The method defined in claim 16, wherein the test system further includes a radio-frequency tester, the method further comprising:
while the device structure under test is mounted on the auxiliary test structure and while the radio-frequency test probes are mated with the device structure under test and the auxiliary test structure, gathering radio-frequency test measurements on the device structure under test with the radio-frequency tester, wherein the radio-frequency test measurements include reflection coefficient and forward transfer coefficient data.

19. The method defined in claim 15, wherein the auxiliary test structure further includes a ground plane formed in a substrate, wherein the second contact member is formed on the substrate and is coupled to the ground plane, and wherein mounting the device structure under test on the auxiliary test structure comprises mounting the device structure under test on the auxiliary test structure so that the ground plane is positioned beneath the signal trace.

20. A method for using a test system to test an antenna feed structure that includes a signal feed contact member, radio-frequency circuitry, and a signal trace each of which is formed on a first substrate, wherein the signal feed contact member is coupled to radio-frequency circuitry via the signal trace, wherein the test system includes a first test probe that has a signal pin and a ground pin and an auxiliary test structure that is formed from a second substrate having upper and lower surfaces, wherein the auxiliary test structure includes a ground contact member formed on the upper surface and a ground plane formed on the lower surface, the method comprising:
with the auxiliary test structure, receiving the antenna feed structure so that that antenna feed structure is attached to the auxiliary test structure and so that the ground plane is positioned beneath the signal trace; and
while the antenna feed structure is attached to the auxiliary test structure, mating the first test probe with the antenna feed structure and the auxiliary test structure so that the signal pin is placed in contact with the signal feed contact member and so that the ground pin is placed in contact with the ground contact member.

21. The method defined in claim 20, wherein the antenna feed structure further includes a first additional contact member that is coupled to the radio-frequency circuitry via the signal trace and includes a second additional contact member that is associated with the first additional contact member, wherein the test system further includes a second test probe that has a signal pin and a ground pin, the method further comprising:
while the antenna feed structure is attached to the auxiliary test structure, mating the second test probe with the antenna feed structure and the auxiliary test structure so that the signal pin of the second test probe is placed in contact with the first additional contact member and so that the ground pin of the second test probe is placed in contact with the second additional contact member.

22. The method defined in claim 21, wherein the test system further includes a radio-frequency tester, the method further comprising:
with the radio-frequency tester, transmitting radio-frequency test signals to the radio-frequency circuitry via the first test probe;
with the radio-frequency tester, receiving corresponding signals from the radio-frequency circuitry via the second test probe; and
computing forward transfer coefficient data based on the transmitted and received signals.

23. The method defined in claim 22 further comprising:
with the radio-frequency tester, receiving signals reflected back from the radio-frequency circuitry via the first test probe; and
computing reflection coefficient data based on the transmitted and reflected signals.

24. The method defined in claim 23 further comprising:
determining whether the radio-frequency circuitry on the antenna feed structure satisfies design criteria by comparing the computed forward transfer and reflection coefficient data to predetermined reference levels.
